(19) United States
(12) Patent Application Publication
(10) Pub. No.: US 2012/0194252 A1
(43) Pub. Date: Aug. 2, 2012

(54) METHOD OF SHIFTING AUTO-ZERO VOLTAGE IN ANALOG COMPARATORS

(75) Inventors: Jeff RYSINSKI, Pasadena, CA (US); Sang-Soo LEE, Cupertino, CA (US)

(73) Assignee: HYNIX SEMICONDUCTOR INC., Icheon-si (KR)

(21) Appl. No.: 13/018,202

(22) Filed: Jan. 31, 2011

(51) Int. Cl. H03L 5/00; H03K 3/01

(52) U.S. Cl. 327/307; 327/534

(57) ABSTRACT

Aspects of the invention provide, inter alia, techniques for shifting auto-zero voltage in analog comparators. An embodiment of the invention may include at least one diode configured transistor to increase a drain voltage of at least one NMOS load transistor. A first switch and a second switch may be implemented to increase a voltage at a gate of a first PMOS input transistor and a voltage at a gate of a second PMOS input transistor when the first switch and the second switch are closed.

### FIELD OF THE INVENTION

Certain embodiments of the invention relate generally to comparators, and more particularly to a method to shift auto-zero voltage in analog comparators.

### BACKGROUND OF THE INVENTION

As computers and processors become more powerful, more and more signal processing is being done in the digital domain. Digital signal processing can perform complex operations to manipulate input data to approximate real world analog signals, and the operations can be performed in real time, or the digital data can be stored for future processing. Since real world signals exist as analog signals, these analog signals need to be converted to equivalent digital signals.

Analog to digital converters (ADCs) are used in many applications, such as, for example, converting analog control signals in industrial applications, audio signals in music, photographic images in digital cameras, and video images in digital video cameras. As with most circuits, there are many different types of ADCs where tradeoffs are made for different limitations. Some, such as the “flash” ADC, are relatively expensive in circuitry and layout space and, accordingly, limited in resolution since every additional bit requires doubling of the number of comparators, but very fast in conversion speed. Others, such as the ramp ADC, can be fairly simple but slow in conversion time. And as the amount of resolution increases, the conversion time will increase.

Accordingly, a particular application needs to take into account various limitations and determine which design best serves its purposes. However, picking a specific design, and possibly modifying it to improve its design, can still present certain challenges that need to be overcome.

For high resolution and high speed imaging, column parallel ADC architecture has become the most widely used ADC in CMOS image sensors. One key challenge to achieving good performance of CMOS image sensors is to reduce noise or other signal offsets from affecting the converted digital data.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Certain embodiments of the invention provide a method to shift auto-zero voltage in analog comparators. Aspects of the invention may comprise at least one diode configured transistor to increase a drain voltage of at least one NMOS load transistor. A first switch and a second switch may be implemented to increase a voltage at a gate of a first PMOS input transistor and a voltage at a gate of a second PMOS input transistor when the first switch and the second switch are closed. The increase in voltage at the gates of the first and second PMOS input transistors may be by a diode voltage that corresponds to the at least one diode configured transistor.

The gate of each of the first and second input transistors may be capacitively coupled to external circuitry, and an output signal may be generated that is dependent on comparison of the voltage level at the gate of the first PMOS input transistor to the voltage level at the gate of the second PMOS input transistor. A second of the at least one load transistor may be diode configured.

These and other advantages, aspects and novel features of the present invention, as well as details of an illustrated embodiment thereof, will be more fully understood from the following description and drawings.

### BRIEF DESCRIPTION OF THE DRAWINGS

A further understanding of the nature and advantages of examples provided by the disclosure may be realized by reference to the remaining portions of the specification and the drawings wherein like reference numerals are used throughout the several drawings to refer to similar components. In some instances, a sub-label is associated with a reference numeral to denote one of multiple similar components. When reference is made to a similar numeral without specification to an existing sub-label, the reference numeral refers to all such similar components.

FIG. 1A is a block diagram of exemplary system for analog to digital conversion that may be used with an embodiment of the invention.

FIG. 1B is a block diagram of exemplary system for analog to digital conversion that may be used with an embodiment of the invention.

FIG. 2 is a block diagram of an exemplary system for column parallel analog digital converters that may be used with an embodiment of the invention.

FIG. 3 is a block diagram of an exemplary comparator architecture that may be used with an embodiment of the invention.

FIG. 4 is a schematic of an exemplary comparator.

FIG. 5 is a schematic of an exemplary comparator with diode level shifting in accordance with an embodiment of the invention.

### DETAILED DESCRIPTION OF THE INVENTION

The following description provides exemplary embodiments only and is not intended to limit the scope, applicability, or configuration of the invention. Rather, the ensuing description of the embodiments will provide those skilled in the art with an enabling description for implementing embodiments of the invention. Various changes may be made in the function and arrangement of elements without departing from the spirit and scope of the invention as set forth in the appended claims.

Thus, various embodiments may omit, substitute, or add various procedures or components as appropriate. For instance, it should be appreciated that in alternative embodiments the methods may be performed in an order different than that described, and that various steps may be added, omitted, or combined. Also, features described with respect to certain embodiments may be combined in various other embodiments. Different aspects and elements of the embodiments may be combined in a similar manner.

It should also be appreciated that the following systems and methods may be components of a larger system, wherein other procedures may take precedence over or otherwise modify their application. Also, a number of steps may be required before, after, or concurrently with the following embodiments.

Embodiments of the present invention will be described in detail with reference to the accompanying drawings such that the scope of the present invention can be easily embodied by those skilled in the art.

Certain embodiments of the invention may be found in a method to shift auto-zero voltage in analog comparators.

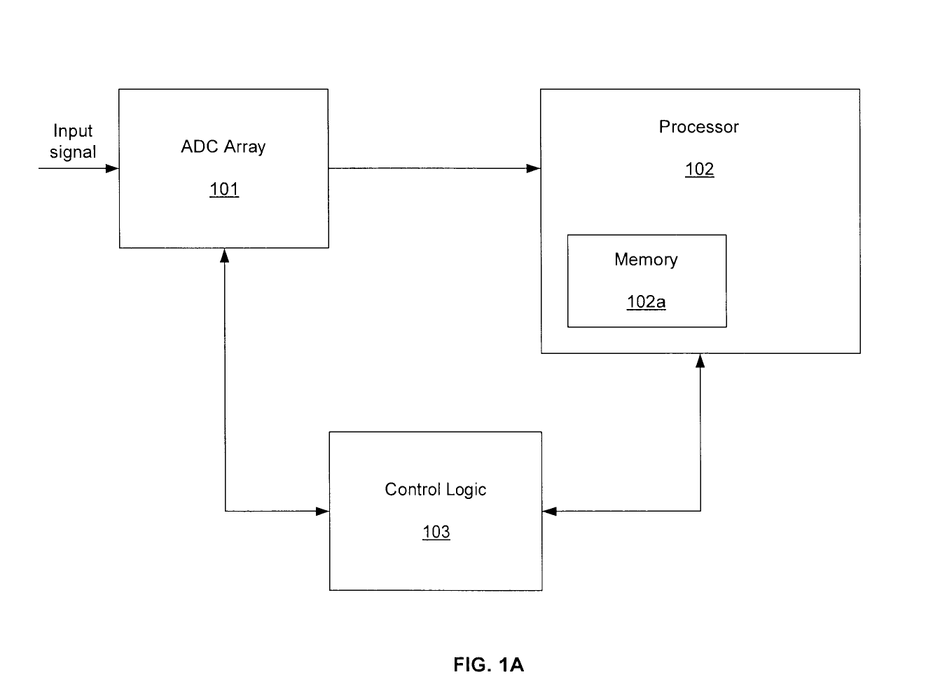

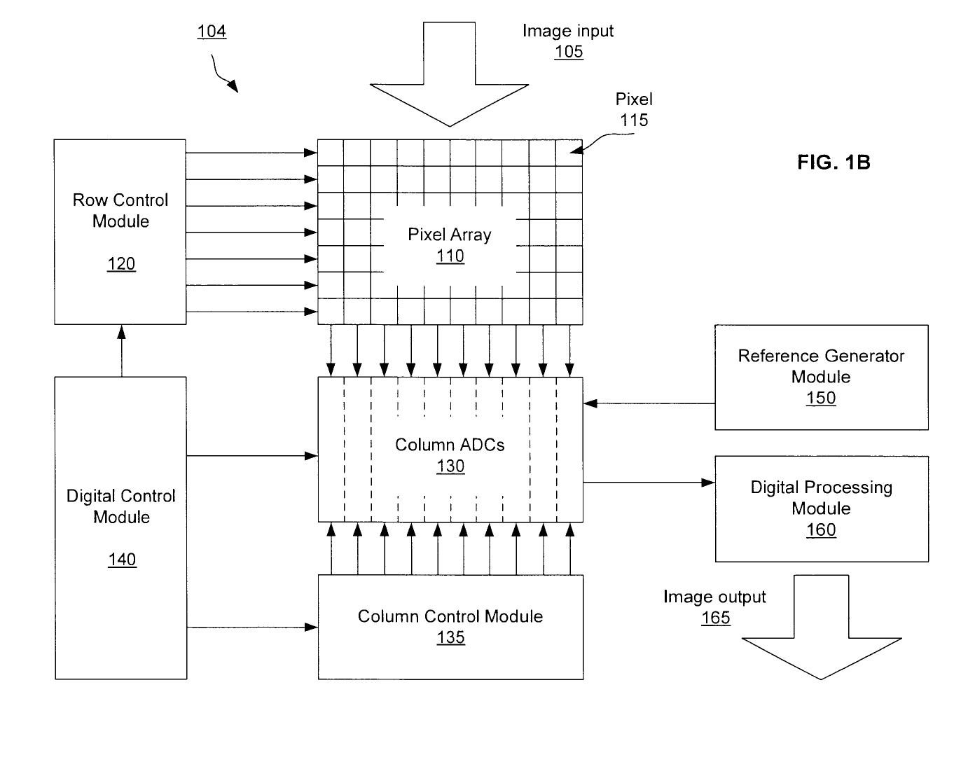

FIG. 1A is a block diagram of exemplary system for analog to digital conversion and digital to analog conversion that may be used with an embodiment of the invention. Referring to FIG. 1A, there is shown a portion of a circuitry for processing input data, comprising the ADC 101, the processor 102, and the control logic 103.

The ADC 101 converts input analog signals, such as, for example, pixel signals from a video image sensor (not shown in FIG. 1A) to equivalent digital signals. The digital signals output by the ADC 101 may be further processed by the processor 102. The processor 102 may, for example, use digital signal processing methods to compress the digital signals from the ADC 101 to a standard video format such as MPEG1, MPEG2, or MPEG4. The processor 102 may also comprise a memory block 102a where code may be stored. This code may be executed by the processor 102 to perform various functions such as, for example, digital signal processing. The memory block 102a may also be used to store digital signals from the ADC 101 and/or digital signals that result from processing the digital signal from the ADC 101.

The control logic 103 may comprise circuitry that generates clocks, control and enable signals, and commands for a variety of modules, such as the ADC 101. For example, the control logic 103 may generate a clock signal that is used for counting in the ADC 101, where the clock signal is not continuously running. A running clock comprises pulses while a non-running clock is in either a low state or a high state. The control logic 103 may also output enable signals that enable the counters in the ADC 101 to count during specific portions of time, and also reset signals.

FIG. 1B is a block diagram of exemplary system for analog to digital conversion that may be used with an embodiment of the invention. Referring to FIG. 1B, there is shown an image processing system 104 that includes a pixel array 110 that may receive analog image input 105 information and output a corresponding signal. The signal is converted into a digital representation by column ADCs 130 and passed to a digital processing module 160 for further processing in the digital domain. The digital processing module 160 outputs a digital image output 165, which is a digital representation of the analog image input 105.

Generally, light interacts with each pixel 115 of the pixel array 110 as analog information. The pixels 115 are arranged in rows and columns, which effectively define the resolution of the pixel array 110 and affect the amount of analog image input 105 data that is converted by the image processing system 104 into digital image output 165 data. Various architectures for this type of conversion typically fall into two categories. According to one category, columnar data from each row of pixels 115 is selected and multiplexed, and the multiplexed data is converted into digital data using a serial ADC approach. According to another category, each row's data is converted column-wise in parallel into digital data by a column-parallel ADC process. FIG. 1B illustrates this second category.

Analog image input 105 data is detected at the pixel array 110. A row control module 120 selects each row's data and passes the data to a set of column ADCs 130. Each column ADC 130 processes one column of the row-wise data (i.e., one pixel 115) in parallel according to a column control module 135 to generate corresponding digital data for the row. The row control module 120 and the column control module 135 may be further controlled by a digital control module 140.

Different architectures are available within the column-parallel ADC approach for performing the analog-to-digital conversion. One such approach is known as “single-slope” ADC. According to an exemplary single-slope ADC approach, a reference signal, generated by a reference generator module 150, ramps with a certain slope and is compared to a pixel 115 signal level generated according to the analog image input 105 received by the corresponding pixel 115. The column ADC 130 detects a crossover point at which the ramp signal crosses the pixel 115 signal level. This crossover point may be detected using analog or digital techniques. For example, various embodiments may use digital techniques (e.g., counters) to determine a value corresponding to the crossover point.

The reference generator module 150 is typically coupled globally with all the column ADCs 130, so that the column ADCs 130 share a common reference signal. Notably, accuracy of the digital output may be affected by accurate detection of the crossover point, which may, in turn, be affected by movement in the reference level. For example, reference levels may change from pixel 115 to pixel 115 and/or may move according to movement (e.g., noise) in the power supply. Because the reference signal is shared across the column ADCs 130, and the column ADCs 130 act on each row in parallel, movement in the reference signal tends to cause row-wise effects (referred to herein as row-wise noise).

In addition to row-wise noise, the column ADCs 130 may experience column-wise noise. In particular, column ADCs 130 may typically experience several sources of column-fixed-pattern noise (CFPN), such as variations in pixel source followers, column comparators, counter, and line memory timing, skew in the clock and ramp signals across the array of ADCs, etc. For example, process variations may cause circuit components from one column ADC 130 to another to be slightly different, thereby causing the column ADCs 130 to have slightly different trigger points, hysteresis, delays, etc. Because the column ADCs 130 are shared from row to row, this CFPN can propagate through the rows, affecting the digital image output 165.

Calibrating the column ADCs 130 to each other can mitigate effects of CFPN sources. Accordingly, typical column ADCs 130 may use an analog and/or digital correlated double sampling (CDS) approach. For example, analog CDS may remove pixel source follower offsets and digital CDS may remove other offsets.

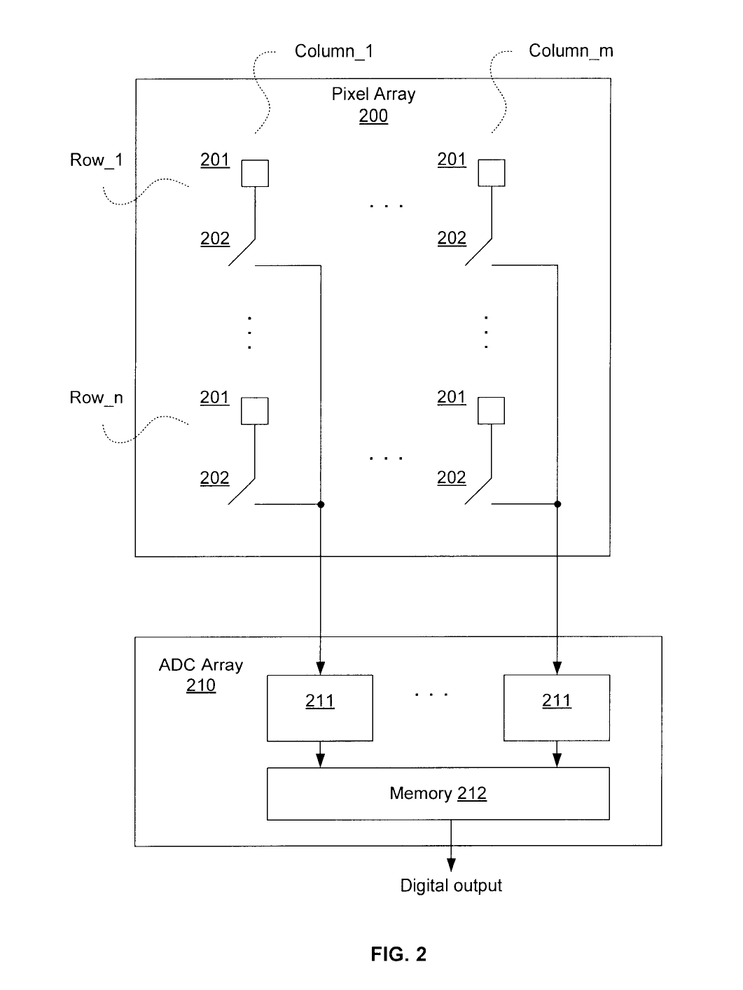

FIG. 2 is a block diagram of an exemplary column parallel analog digital converter configuration that may be used with an embodiment of the invention. Referring to FIG. 2, there are shown a pixel array 200 and an ADC array 210. The pixel array 200 may comprise pixel elements 201 and switching elements 202. The pixel elements 201 may comprise suitable circuitry that outputs, for example, voltage proportional to an amount of light detected by the pixel element 201. The pixel element 201 may be sensitive to specific wavelengths of the impinging light. The ADC array 210 may comprise, for example, an array of ADC elements 211, where each ADC element 211 may correspond to a column of the pixel elements 201. The outputs of the ADC elements 211 may be stored in a memory block 212.

In operation, appropriate control signals from, for example, the control logic 103 may enable the switching elements 202 to open and close appropriately so that output voltage from a particular pixel element 201 is communicated to the ADC array 210. Accordingly, for each column Column_1 to Column_m, only one particular switch element 202 in all of the rows Row_1 to Row_n may be closed during a row scan time so that output voltage from the corresponding pixel element 201 is communicated to the ADC array 210 during that scan time. Therefore a true pixel voltage may be communicated to a corresponding ADC element 211 when only one pixel is selected for the column.

The output voltage from one of the pixel elements 201 in each of the columns Column_1 to Column_m may be converted to equivalent digital values by the corresponding ADC elements 211. However, since there is a plurality of ADC elements 211, each ADC element 211 may need to be calibrated so that each ADC element 211 outputs a similar digital value for a given input. Calibration may be done periodically, for example, such as once during a row scan time or once during a frame. The particular period for calibration may be design and/or implementation dependent.

While FIG. 2 may have been drawn and described as the pixel array 200 having switching elements 202 for the sake of clarity, the invention need not be so limited. For example, the switching elements 202 may be part of the ADC array 210.

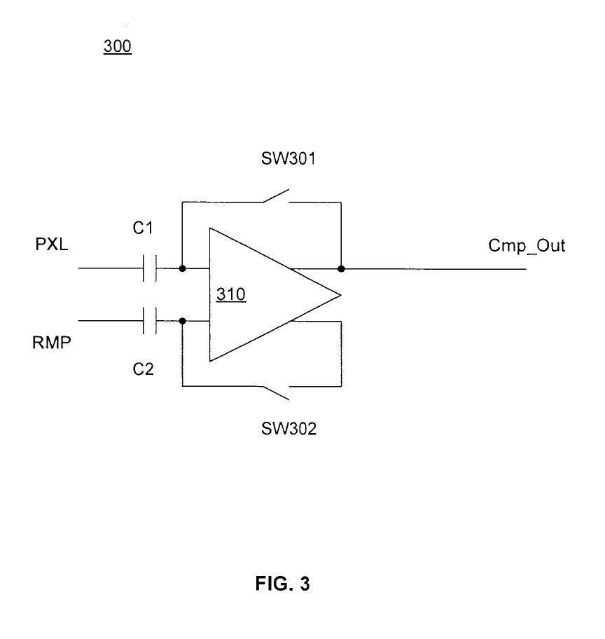

FIG. 3 is a block diagram of an exemplary comparator architecture that may be used with an embodiment of the invention. Referring to FIG. 3, there is shown a comparator element 300, which may be similar to the comparator element 211, comprising comparator 310, coupling capacitors C1 and C2, and switching elements SW301 and SW302.

In operation, the switching elements SW301 and SW302 may be closed by a command from, for example, the control logic 103 to reset inputs of the comparator 310 to a known state. This may be referred to as auto-zeroing the input voltage. The switching elements SW301 and SW302 may then be opened and the input signals PXL and RMP may be applied. The input signal PXL may be, for example, a voltage from a pixel, and the input signal RMP may be a downward sloping voltage signal.

Generally, the input signal RMP may be at a higher initial voltage level than the input signal PXL. Accordingly, output signal Cmp_out of the comparator 310 may be deasserted. However, as the input signal RMP is decreasing in voltage, there may be a point when the level of the input signal RMP crosses the level of the input signal PXL. As the input signal RMP decreases further and the input signal RMP is less than the as the input signal PXL, the comparator may assert the output signal Cmp_out. The output signal Cmp_out may be communicated to, for example, the control logic 103. The control logic 103 may then control various signals that may be used to give a final equivalent digital value of the analog input signal.

While a single stage comparator was shown for the comparator element 300 with respect to FIG. 3, the invention need not be so limited. For example, a two-stage comparator may be used where the comparator 310 may feed another comparator 310. Similarly, other multi-stage comparator may be used.

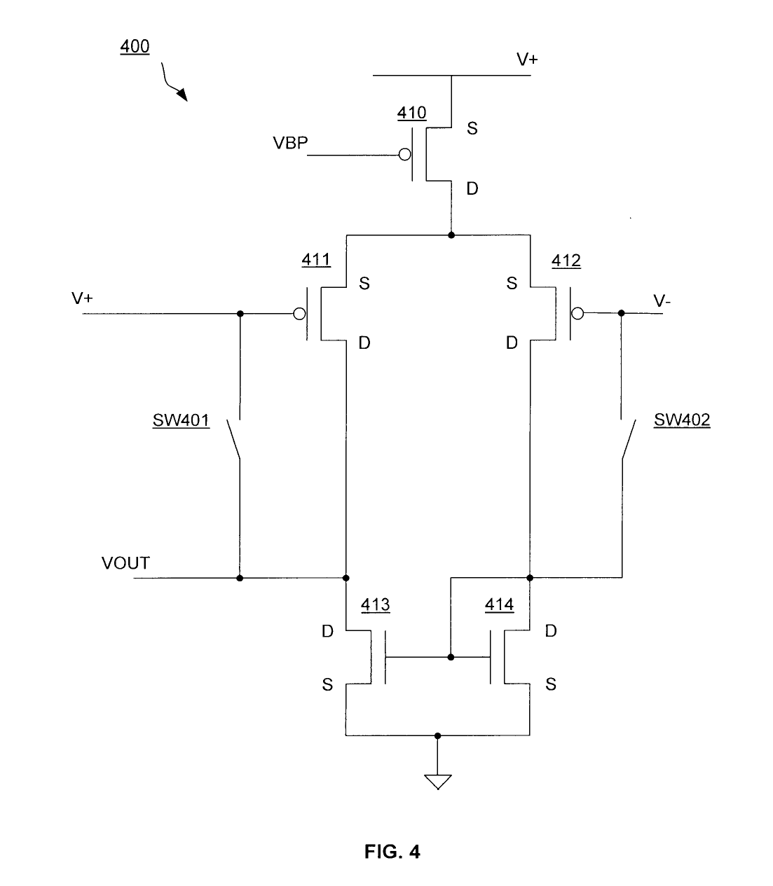

FIG. 4 is a schematic of an exemplary comparator. Referring to FIG. 4, there is shown a schematic for a comparator 400, which may be similar to, for example, the comparator 310. The comparator 400 may comprise PMOS transistors 410, 411, and 412, and NMOS transistors 413 and 414. The comparator 400 may also comprise switching elements SW401 and 402.

A source terminal of the PMOS transistor 410 is coupled to a voltage supply V+, and a drain terminal of the PMOS transistor 410 is coupled to source terminals of the PMOS transistors 411 and 412. An input signal VBP may be applied to a gate terminal of the PMOS transistor 410. The input signal VBP may be used to bias the PMOS transistor 410 so that the PMOS transistor 410 may be a current source.

A drain terminal of the PMOS transistor 411 is coupled to a drain terminal of the NMOS transistor 413. The drain terminal of the PMOS transistor 411 may also be coupled to a first terminal of the switching element SW401 and a gate terminal of the PMOS transistor 411 may be coupled to a second terminal of the switching element SW401. The gate terminal of the PMOS transistor 411 may also receive an input signal V+. Voltage at the node where the drain terminal of the PMOS transistor 411 is coupled to the drain terminal of the NMOS transistor 413 may be a signal VOUT, an output signal of the comparator 400.

A drain terminal of the PMOS transistor 412 is coupled to a drain terminal of the NMOS transistor 414 and to gate terminals of the NMOS transistors 413 and 414. Accordingly, the NMOS transistor 414 may be configured as a diode. The drain terminal of the PMOS transistor 412 may also be coupled to a first terminal of the switching element SW402 and a gate terminal of the PMOS transistor 411 may be coupled to a second terminal of the switching element SW402. An input signal V− may be supplied to a gate terminal of the PMOS transistor 412. Source terminals of the NMOS transistors 413 and 414 are coupled to ground.

In operation, the PMOS transistor 410 may be biased by the biasing signal VBP, and the PMOS transistor 410 may be a current source. The switching elements SW401 and SW402 may be closed to set the input signals V+ and V to a known state, or auto-zero the inputs. The input signals V+ and V− at the gates of the PMOS transistors 411 and 412 may be set to a known state since they may be capacitively coupled via, for example, the coupling capacitors C1 and C2 in FIG. 3. The switching elements SW401 and SW402 may then be opened to allow input signals such as, for example, PXL and RMP to be communicated as V+ and V− to the gates of the PMOS transistors 411 and 412, respectively.

In analog comparators such as the one shown in FIG. 4, voltage at the input of a comparator may be defined by VGS (gate to source voltage) of the load transistor. For example, the VGS of the NMOS transistor 414 defines the input signals V+ and V− when the switching elements SW401 and SW402 are closed.

However, in some applications the full range of the input signal may be higher than VGS of the load device. Accordingly, it may be desirable to reset an input of the comparator 400 to a higher voltage.

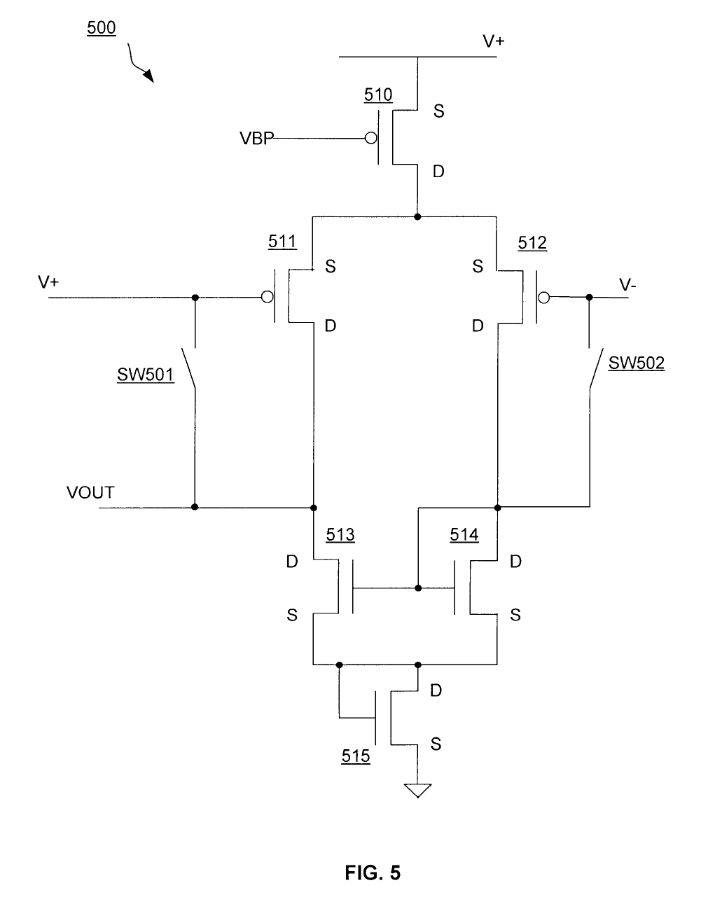

FIG. 5 is a schematic of an exemplary comparator, according to an embodiment of the invention. Referring to FIG. 5, there is shown a schematic for a comparator 500, which may be similar to, for example, the comparator 310. The comparator 500 may comprise PMOS transistors 510, 511, and 512, and NMOS transistors 513, 514, and 515. The comparator 500 may also comprise switching elements SW501 and 502.

A source terminal of the PMOS transistor 510 is coupled to a voltage supply V+, and a drain terminal of the PMOS transistor 510 is coupled to source terminals of the PMOS transistors 511 and 512. An input signal VBP may be applied to a gate terminal of the PMOS transistor 510. The input signal VBP may be used to bias the PMOS transistor 510 so that the PMOS transistor 510 may be a current source.

A drain terminal of the PMOS transistor 511 is coupled to a drain terminal of the NMOS transistor 513. The drain terminal of the PMOS transistor 511 may also be coupled to a first terminal of the switching element SW501 and a gate terminal of the PMOS transistor 511 may be coupled to a second terminal of the switching element SW501. The gate terminal of the PMOS transistor 511 may also receive an input signal V+. Voltage at the node where the drain terminal of the PMOS transistor 511 is coupled to the drain terminal of the NMOS transistor 513 may be a signal VOUT, an output signal of the comparator 500.

A drain terminal of the PMOS transistor 512 is coupled to a drain terminal of the NMOS transistor 514 and to gate terminals of the NMOS transistors 513 and 514. Accordingly, the NMOS transistor 514 may be configured as a diode. The drain terminal of the PMOS transistor 512 may also be coupled to a first terminal of the switching element SW502 and a gate terminal of the PMOS transistor 512 may be coupled to a second terminal of the switching element SW502. An input signal V− may be supplied to a gate terminal of the PMOS transistor 512.

Source terminals of the NMOS transistors 513 and 514 may be coupled to a drain terminal and a gate terminal of the NMOS transistor 515. The source terminal of the NMOS transistor 515 may be coupled to ground. Accordingly, the NMOS transistor 515 may be configured as a diode, and the drain terminals of the NMOS transistors 513 and 514 may be at a diode voltage drop of the NMOS transistor 515.

In operation, the PMOS transistor 510 may be biased by the biasing signal VBP, and the PMOS transistor 510 may be a current source. The switching elements SW501 and SW502 may be closed to set the input signals V+ and V to a known state, or auto-zero the inputs. The input signals V+ and V− at the gates of the PMOS transistors 511 and 512 may be set to a known state since they may be capacitively coupled via, for example, the coupling capacitors C1 and C2 in FIG. 3. The switching elements SW501 and SW502 may then be opened to allow input signals such as, for example, PXL and RMP to be communicated as V+ and V− to the gates of the PMOS transistors 511 and 512, respectively.

As explained with respect to FIG. 4, voltage at the input of a comparator may be defined by VGS (gate to source voltage) of the load transistor. For example, the VGS of the NMOS transistor 514 defines the input signals V+ and V− when the switching elements SW501 and SW502 are closed. However, in addition to VGS of the NMOS transistor 514, the voltage at the gates of the PMOS transistors 511 and 512 is raised by the diode drop voltage of the NMOS transistor 515. Accordingly, an input signal range may be higher than VGS of the load device by the diode voltage drop of the NMOS transistor 515.

Although some embodiments of the invention have been described, the invention is not so limited. For example, while specific transistors may have been described as being NMOS transistors and others as being PMOS transistors, these specific transistors may be changed to different types to perform the desired functions of various embodiments of the invention. Also, the auto-zeroed voltage at the inputs may be raised by adding more diode configured transistors, or by appropriately building diode configured transistors. Additionally, various other circuitry may be designed as various embodiments of the invention.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for processing signals, the method comprising:
diode configuring at least one transistor to increase a drain voltage of at least one load transistor; and
implementing a first switch to increase a voltage at a gate of a first input transistor by a diode voltage corresponding to the at least one diode configured transistor when the first switch is closed.

2. The method according to claim 1, comprising implementing a second switch to increase a voltage at a gate of a second input transistor by the diode voltage corresponding to the at least one diode configured transistor when the second switch is closed.

3. The method according to claim 2, comprising capacitively coupling the gate of the second input transistor to external circuitry.

4. The method according to claim 2, wherein an output signal is dependent on comparison of a voltage level at the gate of the first input transistor to a voltage level at the gate of the second input transistor.

5. The method according to claim 2, wherein the first and second input transistors are PMOS transistors.

6. The method according to claim 1, comprising capacitively coupling the gate of the first input transistor to external circuitry.

7. The method according to claim 1, wherein the at least one load transistor is an NMOS transistors.

8. The method according to claim 1, wherein a second of the at least one load transistor is diode configured.

9. A system for processing signals, the system comprising:
at least one transistor in a diode configuration to increase a drain voltage of at least one load transistor; and
a first switch implemented to increase a voltage at a gate of a first input transistor by a diode voltage corresponding to the at least one diode configured transistor when the first switch is closed.

10. The system according to claim 9, comprising a second switch implemented to increase a voltage at a gate of a second input transistor by the diode voltage corresponding to the at least one diode configured transistor when the second switch is closed.

11. The system according to claim 10, comprising a coupling capacitor coupling the gate of the second input transistor to external circuitry.

12. The system according to claim 10, wherein an output signal is dependent on comparison of a voltage level at the gate of the first input transistor to a voltage level at the gate of the second input transistor.

13. The system according to claim 10, wherein the first and second input transistors are PMOS transistors.

14. The system according to claim 9, comprising a coupling capacitor coupling the gate of the first input transistor to external circuitry.

15. The system according to claim 9, wherein the at least one load transistor is an NMOS transistors.

16. The system according to claim 9, wherein a second of the at least one load transistor is diode configured.

17. Circuitry for processing signals, the circuitry comprising:
a first PMOS transistor with a source terminal coupled to a positive voltage supply;
a drain terminal of the first PMOS transistor coupled to a source terminal of a second PMOS transistor and to a source terminal of a third PMOS transistor;
a drain terminal of the first NMOS transistor coupled to a drain terminal of the second PMOS transistor and to a first terminal of a first switch;
a second terminal of the first switch coupled to a gate of the second PMOS transistor;
a drain terminal of a second NMOS transistor coupled to a gate of the second NMOS transistor, a gate of the first NMOS transistor, a drain of the third PMOS transistor, and to a first terminal is of a second switch;
a second terminal of the second switch coupled to a gate of the third PMOS transistor;
a source terminal of each of the first NMOS transistor and second NMOS transistor coupled to a gate of a third NMOS transistor and to a drain of the third NMOS transistor; and
a source terminal of the third NMOS transistor coupled to ground.

18. The circuitry according to claim 17, wherein:
a biasing signal is applied to a gate terminal of the first PMOS transistor;
a first input signal is applied to a gate terminal of the second PMOS transistor; and
a second input signal is applied to a gate terminal of the third PMOS transistor.

19. The circuitry according to claim 17, wherein an output signal is at the node where the drain terminal of the second PMOS transistor is coupled to the drain terminal of the first NMOS transistor.

20. The circuitry according to claim 17, wherein the gate of the second PMOS transistor and the gate of the third PMOS transistor are capacitively coupled to external circuitry.
